(19) United States
(12) Patent Application Publication
(10) Pub. No.: US 2009/0079006 A1
(43) Pub. Date: Mar. 26, 2009

(54) SEMICONDUCTOR APPARATUS

(75) Inventors: Bungo TANAKA, Saitama-ken (JP); Akio TAKANO, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/236,954

(22) Filed: Sep. 24, 2008

(30) Foreign Application Priority Data
Sep. 25, 2007 (JP) 2007-247914

(51) Int. Cl. H01L 27/088

(52) U.S. Cl. 257/368; 257/E27.06

(57) ABSTRACT

A semiconductor apparatus includes: a semiconductor device including a semiconductor layer, a first metal main electrode provided on the semiconductor layer and having a first region and a second region, and a metal gate interconnect provided on the semiconductor layer and insulated from and interposed between the first region and the second region; a lead; and a conductive member made of a metal and connecting the first metal main electrode to the lead. The conductive member is bonded to the first region and the second region so as to cover the metal gate interconnect, and the conductive member has a recess on its lower surface above the metal gate interconnect to be spaced from the metal gate interconnect.

### CROSS-REFERENCE TO RELATED APPLICATIONS

This application is based upon and claims the benefit of priority from the prior Japanese Patent Application No. 2007-247914, filed on Sep. 25, 2007; the entire contents of which are incorporated herein by reference.

### BACKGROUND OF THE INVENTION

1. Field of the Invention

This invention relates to a semiconductor apparatus.

2. Background Art

Power MOSFET and other power semiconductor devices are required to reduce on-resistance, thereby reducing power loss.

To this end, as a connecting means between the source electrode and the package lead where a large current flows, a structure based on a plate-like or ribbon-like strap member made of copper (Cu) or aluminum (Al) can be used instead of a bonding wire.

For example, an Al strap member can be bonded to the source electrode by supersonic bonding. However, if a supersonic wave is applied while the gate metal interconnect layer still remains, a short circuit is likely to occur between the source electrode and the gate metal interconnect layer. If a gate polysilicon interconnect layer is used instead of the gate metal interconnect layer, short circuiting can be reduced.

Japanese Patent No. 3637330 discloses a technique related to a semiconductor apparatus provided with an Al strap member. This technique provides a semiconductor apparatus with reduced gate internal resistance, including a gate polysilicon interconnect layer with part of its surface being a silicide layer, and a strap member coupled to the source electrode. However, the silicide layer has a higher specific resistance than the metal interconnect layer, and the reduction of the gate internal resistance is insufficient.

### SUMMARY OF THE INVENTION

According to an aspect of the invention, there is provided a semiconductor apparatus including: a semiconductor device including a semiconductor layer, a first metal main electrode provided on the semiconductor layer and having a first region and a second region, and a metal gate interconnect provided on the semiconductor layer and insulated from and interposed between the first region and the second region; a lead; and a conductive member made of a metal and connecting the first metal main electrode to the lead, the conductive member being bonded to the first region and the second region so as to cover the metal gate interconnect, and the conductive member having a recess on its lower surface above the metal gate interconnect to be spaced from the metal gate interconnect.

According to another aspect of the invention, there is provided a semiconductor apparatus including: a semiconductor device including a semiconductor layer, a first metal main electrode provided on the semiconductor layer and having a first region and a second region, and a metal gate interconnect provided on the semiconductor layer and insulated from and interposed between the first region and the second region; a first bonding member provided on the first region; a second bonding member provided on the second region; a lead; and a conductive member made of a metal and connecting the first metal main electrode to the lead, the conductive member being spaced from the metal gate interconnect and bonded to the first bonding member and the second bonding member so as to cover the metal gate interconnect.

According to still another aspect of the invention, there is provided a semiconductor apparatus including: a semiconductor device including a semiconductor layer, a first metal main electrode provided on the semiconductor layer and having a first region and a second region, and a metal gate interconnect provided on the semiconductor layer and insulated from and interposed between the first region and the second region; a lead; and a conductive member made of a metal and connecting the first metal main electrode to the lead, the conductive member being spaced from the metal gate interconnect via an insulating layer made of an insulating material, and being bonded to the first region and the second region so as to cover the metal gate interconnect.

### BRIEF DESCRIPTION OF THE DRAWINGS

FIGS. 1A to 1D are schematic views of a semiconductor apparatus according to a first embodiment;

FIGS. 2A and 2B are schematic views of a semiconductor apparatus according to a comparative example;

FIG. 3 is a schematic plan view of the semiconductor device mounted on a lead frame;

FIGS. 4A and 4B are schematic views of a semiconductor apparatus according to a second embodiment;

FIGS. 5A and 5B are schematic views of a semiconductor apparatus according to d third embodiment;

FIGS. 6A to 6C are schematic views of a semiconductor apparatus according to a fourth embodiment; and

FIGS. 7A and 7B are schematic views of a semiconductor apparatus according to a modification example of the fourth embodiment.

### DETAILED DESCRIPTION OF THE INVENTION

Embodiments of the invention will now be described with reference to the drawings.

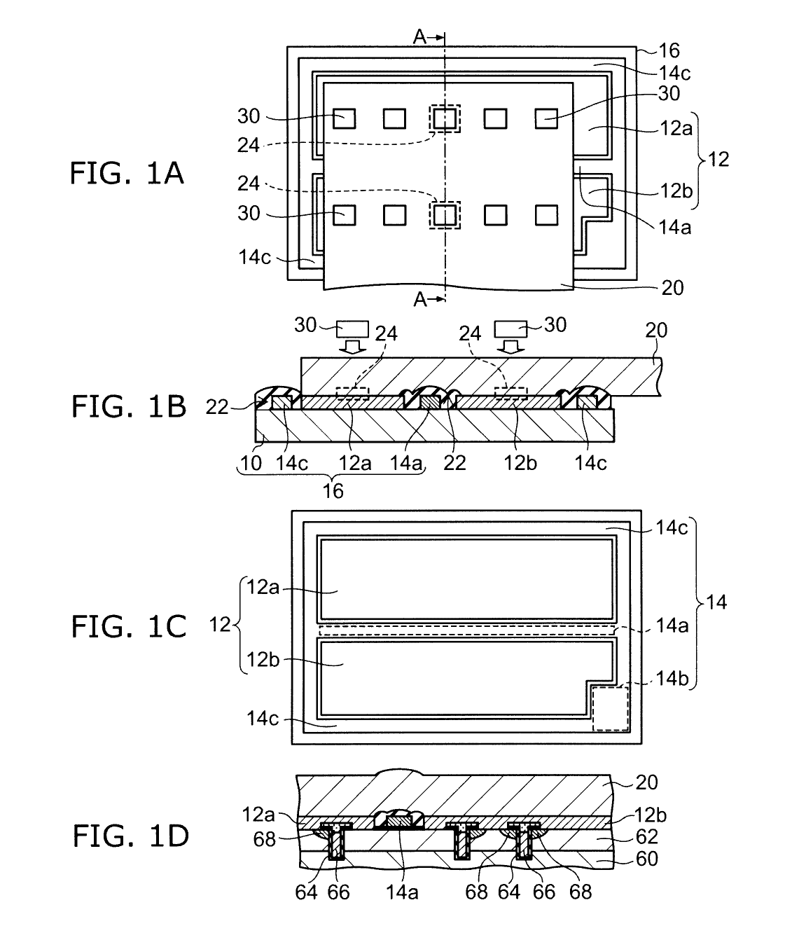

FIG. 1 shows a semiconductor apparatus according to a first embodiment of the invention, in which FIG. 1A is a schematic plan view, FIB. 1B is a schematic cross-sectional view taken along line A-A, FIG. 1C is a schematic plan view of a semiconductor device, and FIG. 1D is a schematic cross-sectional view in the vicinity of the metal gate interconnect of the semiconductor device.

This embodiment is described assuming that the semiconductor device 16 is a MOSFET (metal oxide semiconductor field effect transistor). However, the semiconductor device 16 is not limited thereto, but illustratively an IGBT (insulated gate bipolar transistor) and the like. The MOSFET includes a semiconductor layer 10 having a drain region of a first conductivity type, a base region of a second conductivity type, and a plurality of source regions of the first conductivity type.

FIG. 1D shows the semiconductor layer 10 in detail. More specifically, for example, a p-type base region 62 is selectively formed on an n-type substrate 60. A trench is formed through the p-type base region 62 from the frontside. In the trench, a gate insulating film 64 is formed, and a trench gate electrode 66 illustratively made of polysilicon is embedded. The trench gate electrode 66 is electrically connected to a metal gate interconnect 14. An n⁺-type source region 68 is selectively formed in the surface of the p-type base region 62 around the trench, and an n⁺-type drain region is formed at the bottom of the substrate 60. The trench can be illustratively extended in a direction perpendicular or parallel to the inner finger 14a of the metal gate interconnect 14. Furthermore, two source metal electrodes 12a, 12b are provided to sandwich the inner finger 14a and are connected to the n⁺-type source regions 68, respectively.

A plurality of n⁺-type source regions 68 are connected to the regions 12a, 12b of the source metal electrode 12, respectively. In the trench provided in the surface of the semiconductor layer 10, for example, the trench gate electrode 66 facing the p-type base region 62 across the gate insulating film 64 is connected to the metal gate interconnect 14. An insulating layer is provided between the metal gate interconnect 14 and the surface of the semiconductor layer 10.

As in FIG. 1C, the source metal electrode 12 is divided into a plurality of regions 12a, 12b, and an inner finger (extending portion) 14a is placed between the two adjacent regions 12a and 12b. The metal gate interconnect 14 is composed of the inner finger 14a represented by the dashed line, a pad 14b represented by the dashed line, and an outer finger 14c. The source metal electrode 12 and the metal gate interconnect 14 have a generally equal thickness. For example, a metal film illustratively made of Al having a thickness of several μm can be laminated in the same process and patterned using the photolithography process. While FIG. 1C shows an example in which a plurality of regions 12a, 12b are completely divided, the invention is not limited thereto. It is also possible to use a pattern in which the regions 12a, 12b are partly connected.

In FIG. 1B, the source metal electrode 12 has a plurality of regions 12a, 12b, and the inner finger 14a of the metal gate interconnect 14 is placed therebetween. The strap member 20, which is a conductive member, is spaced from the metal gate interconnect 14 astride the inner finger 14a and is not in contact with the metal gate interconnect 14. The two regions 12a, 12b constituting the source metal electrode 12 are bonded together by the strap member 20. The material of the strap member 20 is preferably Al or Cu, and more preferably Al, because it can then be easily bonded by supersonic bonding to the source metal electrode 12 made of Al at room temperature.

It is noted that the invention is not limited to the structure in which the source metal electrode 12 is made of a plurality of regions with the metal gate interconnect 14 placed therebetween. The electrode to which the strap member 20 is connected can be the drain metal electrode instead of the source metal electrode. In that case, the metal gate interconnect 14 can be placed between a plurality of drain metal electrodes.

A power MOSFET is required to reduce drain-source on-resistance in large current operation, thereby reducing power loss. Here, it is important to decrease not only the device internal resistance of the semiconductor device 16, but also the connection resistance between the source metal electrode 12 and the package lead. A large number of bonding wires are needed for the source current, because it is larger than the gate current. However, even if the number of bonding wires is increased, there is a limit to reducing the resistance of the connecting portion. Thus, a strap member 20 having a large cross-sectional area is used to connect the source metal electrode 12, thereby reducing the resistance of the connecting portion. Furthermore, the process of supersonic bonding using a strap connecting jig is simpler than the wire bonding process with a large number of wires, and facilitates streamlining the assembly process.

In this case, if the inner finger 14a is covered with an insulator material to form an insulating layer 22, short circuiting between the strap member 20 and the inner finger 14a is easily prevented, and the reliability and manufacturing yield can be improved. Furthermore, because the insulating layer 22 made of an insulator material is convex upward, the planar strap member 20 made of a soft material such as Al is slightly dished in supersonic bonding to form a recess. Despite the slight recess, insulation between the inner finger 14a and the strap member 20 can be maintained because the insulating layer 22 is interposed therebetween. Furthermore, the tip of the horn of the strap connecting jig 30 used for supersonic bonding is placed above the plurality of regions 12a, 12b of the source metal electrode 12 as in FIG. 1A. Therefore, the upper surface of the strap member 20 becomes slightly concave upward by the tip of the horn after supersonic bonding. High bonding strength can be obtained in the vicinity of the supersonic bonding portion 24 between the lower surface of the strap member 20 and the upper surface of the regions 12a and 12b. Thus, short circuiting between the strap member 20 and the inner finger 14a due to supersonic bonding is prevented more reliably, and the reliability and yield can be further improved.

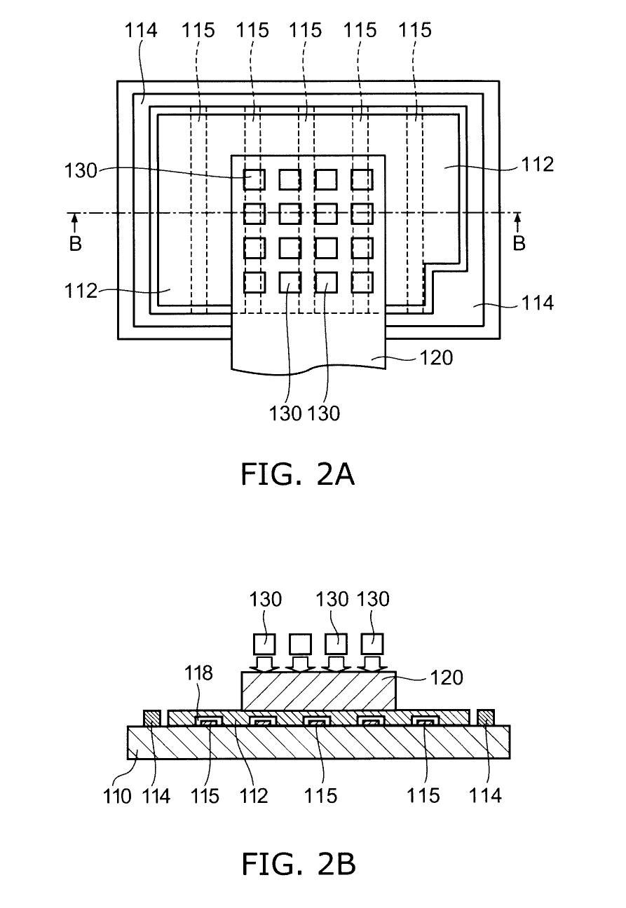

FIG. 2 shows a semiconductor apparatus according to a comparative example, in which FIG. 2A is a schematic plan view, and FIB. 2B is a schematic cross-sectional view taken along line B-B. A gate polysilicon interconnect layer 115 serving as an extraction interconnect layer is provided between two cell regions constituting a semiconductor layer 110. The upper portion of the gate polysilicon interconnect layer 115 is silicidized, and an interlayer insulating film 118 is provided to cover the gate polysilicon interconnect layer 115. A gate metal electrode 114 entirely surrounding the cell region is electrically connected to the gate polysilicon interconnect layer 115. Furthermore, a source metal electrode 112 is provided to link a plurality of source regions astride the gate polysilicon interconnect layer 115. Thus, even if the connecting horn of a strap connecting jig 130 is placed above the gate polysilicon interconnect layer 115 as in FIG. 2A, short circuiting can be avoided because there is no metal electrode.

However, the silicide layer has a higher specific resistance than metal, and the gate resistance can be reduced only to approximately 1 to 2Ω. A high gate resistance prevents the cell region of the semiconductor layer 110 from operating uniformly. To achieve a lower gate resistance, the number of fingers of the gate polysilicon interconnect layer 115 needs to be increased. Here, if the chip size remains unchanged, the effective device area decreases. Instead, if the effective device area is maintained, the chip size increases, which makes it difficult to downsize the semiconductor apparatus. Furthermore, formation of the silicide layer increases the number of steps in chip manufacturing, which results in increased cost.

On the other hand, two-layer metallization can be used for strap bonding above the inner finger. However, this method is insufficient to prevent short circuiting between the source metal electrode and the gate metal electrode due to cracks in the interlayer film.

In contrast, in this embodiment, the inner finger 14a serving as a gate metal interconnect can reduce the gate resistance as well as facilitates uniform operation of the cell region and downsizing of the semiconductor device 16. Furthermore, the bonding portion 24 is provided above the source metal electrode 12 to prevent short circuiting between the strap member 20 and the inner finger 14a. Thus, this embodiment can provide a semiconductor apparatus having a strap structure with improved reliability while maintaining low gate resistance.

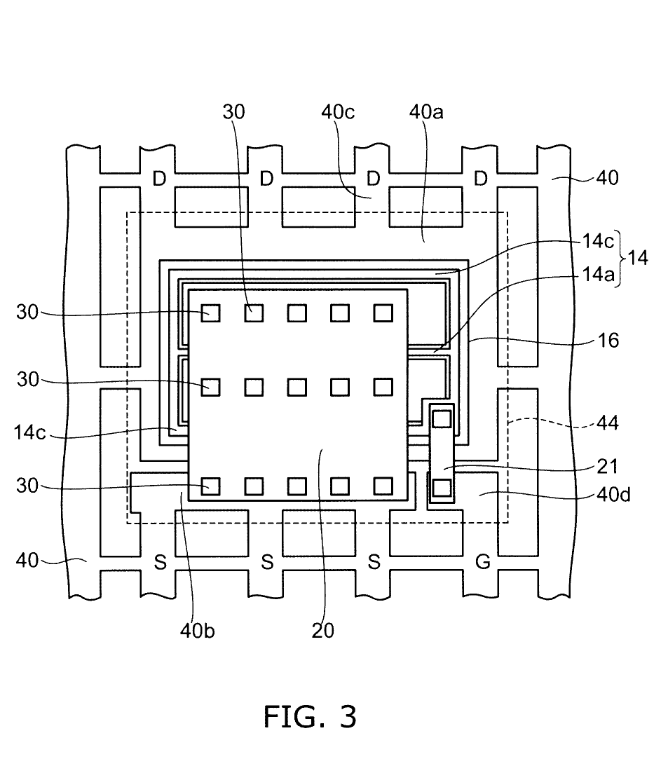

FIG. 3 is a schematic plan view of the semiconductor device mounted on a lead frame. The semiconductor device 16 is mounted on the die pad 40a of the lead frame 40. The source metal electrode 12 is bonded to the inner lead 40b by the strap member 20, and the pad 14b of the metal gate interconnect 14 is bonded to the inner lead 40d by the strap member 21. The die pad 40a continues to the lead 40c serving as a drain terminal. By the transfer molding process, a resin molded body 44 as represented by the dashed line is formed on the lead frame 40 with the semiconductor device 16 mounted thereon. Then, by the lead cutting and forming process, a semiconductor apparatus is completed. In this figure, it is also possible to connect the pad 14b to the inner lead 40d by a bonding wire. It is noted that the portion of a lead of the lead frame 40 embedded inside the resin molded body 44 is referred to as an inner lead.

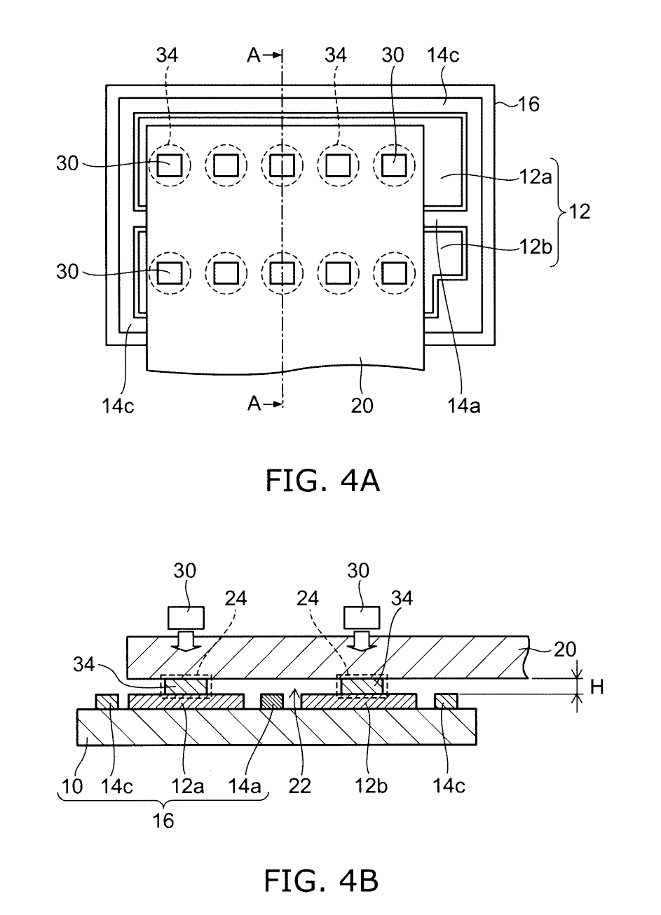

FIG. 4 shows a semiconductor apparatus according to a second embodiment, in which FIG. 4A is a schematic plan view, and FIB. 4B is a schematic cross-sectional view taken along line A-A. A bump (bonding member) 34 is formed between a plurality of regions 12a, 12b of the source metal electrode 12 and the strap member 20. A step difference H generally equal to the thickness of the bump 34 is produced between the upper surface of the inner finger 14a and the lower surface of the strap member 20. The strap member 20 is spaced from the inner finger 14a, and an insulating layer 22 is formed more reliably. More preferably, the inner finger 14a is covered with an insulator to further enhance insulation. The insulating layer 22 only needs to include at least one of an insulator material and air.

In this embodiment, a gold stud bump 34 can be formed on the plurality of regions 12a, 12b using a wire bonder. More specifically, the tip of a gold wire is melted by electric discharge to form a ball, which is bonded to the plurality of regions 12a, 12b, and the wire is cut. Then, the tip of the horn of a strap connecting jig 30 is aligned above the bump 34 to apply a supersonic wave to the strap member 20 from above, thereby bonding the bump 34 to the strap member 20. The bonding portion 24 represented by the dashed line includes the lower surface of the strap member 20, the bump 34, and the upper surface of the source electrode 12. The material of the bump 34 can be gold (Au), solder, Cu, Al—Cu, Al—Si—Cu, Ti, TiN, tungsten (W), or TiW. Among them, Au is preferable because it is rich in conductivity, ductility, and malleability, and hence the contact resistance can be decreased while reliably maintaining contact.

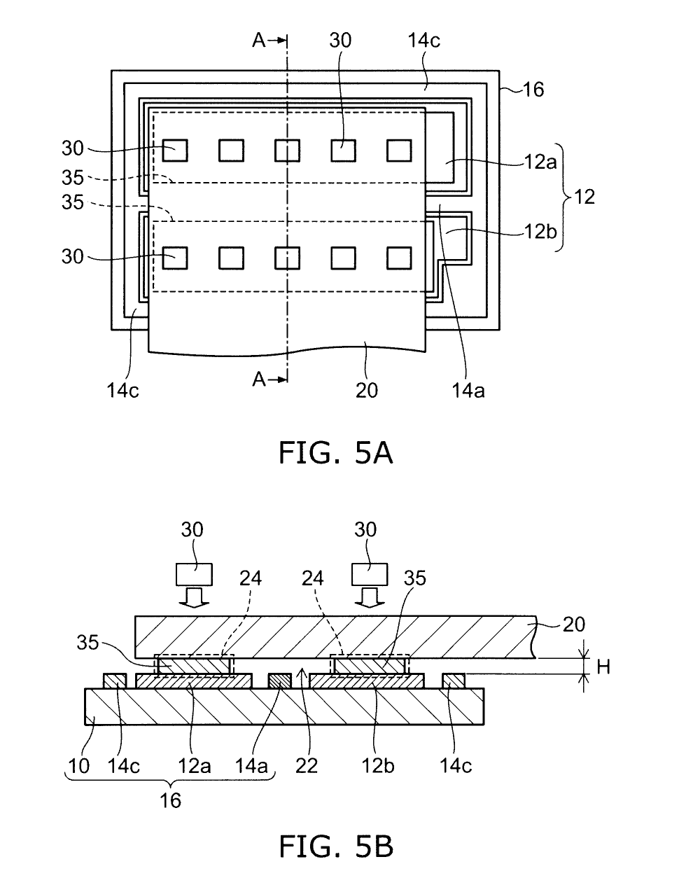

FIG. 5 shows a semiconductor apparatus according to a third embodiment, in which FIG. 5A is a schematic plan view, and FIB. 5B is a schematic cross-sectional view taken along line A-A. An electrode member (bonding member) 35 is provided between the plurality of regions 12a, 12b and the strap member 20. Preferably, the electrode member 35 is provided so as not to protrude from the plurality of regions 12a, 12b of the source metal electrode 12. Furthermore, as in FIG. 5, when a plurality of tips of the horns serving as a strap connecting jig 30 are placed above one region of the source metal electrode 12, a plate-like electrode member 35 extending in the extending direction of the inner finger 14a can alleviate the accuracy of the horn position of the strap connecting jig 30 in the process of bonding to the strap member 20, and the process can be made simpler than that using bumps. Thus, a step difference H generally equal to the thickness of the electrode member 35 is formed between the upper surface of the inner finger 14a and the lower surface of the strap member 20. The strap member 20 is spaced from the inner finger 14a, and an insulating layer 22 is formed more reliably. More preferably, the inner finger 14a is covered with an insulator to further enhance insulation.

The electrode member 35 can be formed by electroplating on the plurality of regions 12a, 12b. Alternatively, the electrode member 35 can be made of a metal plate and mechanically bonded. The bonding portion 24 includes the lower surface of the strap member 20, the electrode member 35, and the upper surface of the source metal electrode 12. The material of the electrode member 35 can be Au, solder, Cu, Al—Cu, Al—Si—Cu, Ti, TiN, W, or TiW. Among them, Au is preferable because it is rich in conductivity, ductility, and malleability, and hence the contact resistance can be decreased while reliably maintaining contact.

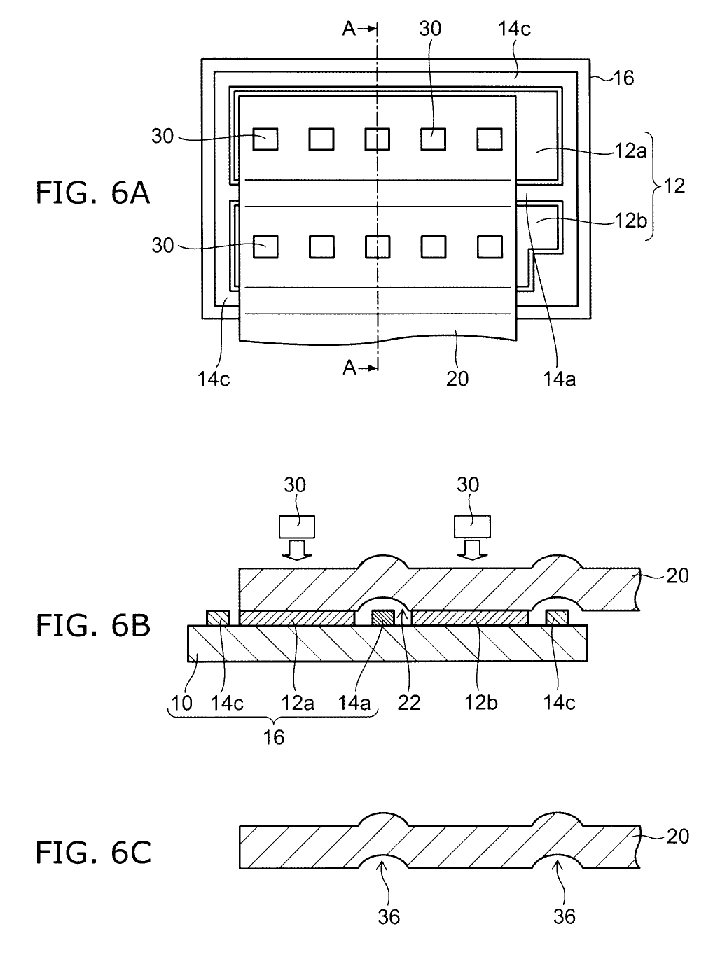

FIG. 6 shows a semiconductor apparatus according to a fourth embodiment, in which FIG. 6A is a schematic plan view, FIB. 6B is a schematic cross-sectional view taken along line A-A, and FIG. 6C shows a processed strap member. In contrast to the first to third embodiment, a loop-shaped or rectangular recess 36 is formed in advance on the lower surface of the strap member 20 as in FIG. 6C. The strap member 20 is aligned so that the recess 36 is opposed to and spaced from the inner finger 14a, and the horn of the strap connecting jig 30 is placed with respect to the strap member 20 above the plurality of regions 12a, 12b as in FIG. 6 for bonding. More preferably, the inner finger 14a is covered with an insulator to further enhance insulation. This embodiment can more easily realize insulation between the metal gate interconnect 14 and the strap member 20 by processing the shape of the strap member 20.

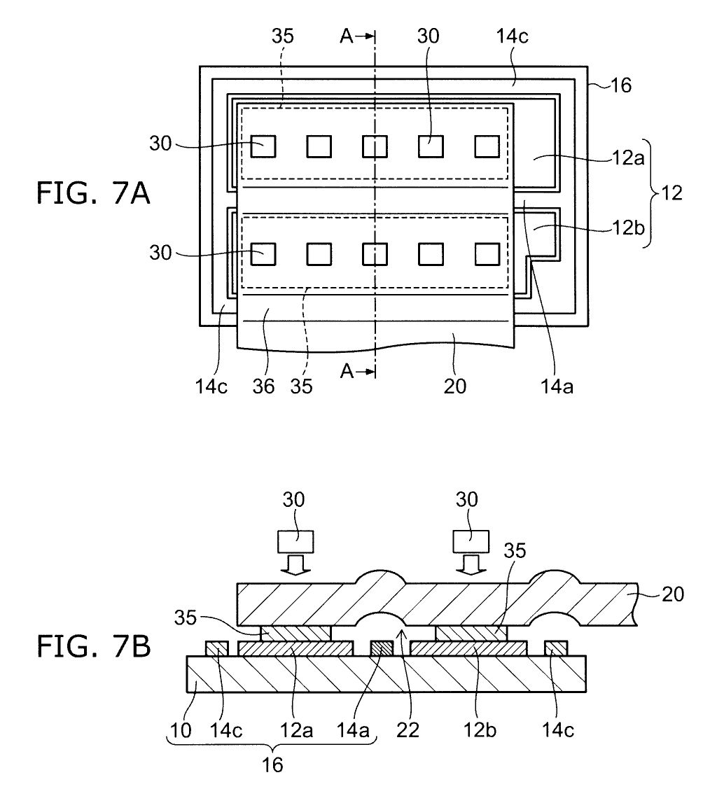

FIG. 7 shows a semiconductor apparatus according to a variation of the fourth embodiment, in which FIG. 7A is a schematic plan view, and FIB. 7B is a schematic cross-sectional view taken along line A-A. The strap member 20 has recesses 36 as in the fourth embodiment, and the electrode member 35 shown in FIG. 5 is provided between the strap member 20 and the plurality of regions 12a, 12b. By such a combined structure, the metal gate interconnect 14 can be spaced from the strap member 20 to more reliably achieve insulation therebetween. Furthermore, it is also possible to use a combined structure in which the bump 34 shown in FIG. 4 is provided between the strap member 20 having the recesses 36 and the plurality of regions 12a, 12b.

The second to fourth embodiment and the variation associated therewith reduce the gate resistance, enable uniform operation inside the device, and facilitate downsizing the semiconductor device. Furthermore, it is possible to provide a semiconductor apparatus having a strap structure with improved reliability and yield while maintaining low drain-source on-resistance.

The embodiments of the invention have been described with reference to the drawings. However, the invention is not limited to these embodiments. The material, shape, size, and layout of the semiconductor device, semiconductor layer, source metal electrode, metal gate interconnect, strap member, bump, electrode member, insulating layer, and lead frame constituting the semiconductor apparatus can be modified by those skilled in the art, and such modifications are also encompassed within the scope of the invention as long as they do not depart from the spirit of the invention.

1. A semiconductor apparatus comprising:
a semiconductor device including a semiconductor layer, a first metal main electrode provided on the semiconductor layer and having a first region and a second region, and a metal gate interconnect provided on the semiconductor layer and insulated from and interposed between the first region and the second region;
a lead; and
a conductive member made of a metal and connecting the first metal main electrode to the lead,
the conductive member being bonded to the first region and the second region so as to cover the metal gate interconnect, and the conductive member having a recess on its lower surface above the metal gate interconnect to be spaced from the metal gate interconnect.

2. The semiconductor apparatus according to claim 1, wherein the first metal main electrode and the metal gate interconnect have a generally equal thickness.

3. The semiconductor apparatus according to claim 1, wherein the conductive member is made of any of Al and Cu.

4. The semiconductor apparatus according to claim 1, wherein the first metal main electrode is made of Al.

5. The semiconductor apparatus according to claim 1, wherein the semiconductor device is a MOSFET, and the first main electrode is a source electrode.

6. A semiconductor apparatus comprising:
a semiconductor device including a semiconductor layer, a first metal main electrode provided on the semiconductor layer and having a first region and a second region, and a metal gate interconnect provided on the semiconductor layer and insulated from and interposed between the first region and the second region;
a first bonding member provided on the first region;
a second bonding member provided on the second region;
a lead; and
a conductive member made of a metal and connecting the first metal main electrode to the lead,
the conductive member being spaced from the metal gate interconnect and bonded to the first bonding member and the second bonding member so as to cover the metal gate interconnect.

7. The semiconductor apparatus according to claim 6, wherein the conductive member has a recess on its lower surface above the metal gate interconnect.

8. The semiconductor apparatus according to claim 6, wherein the first and second bonding member are each made of a bump.

9. The semiconductor apparatus according to claim 6, wherein the first and second bonding member are each made of an electrode member.

10. The semiconductor apparatus according to claim 6, wherein the first and second bonding member contain at least one of Au, Cu, Al—Cu, Al—Si—Cu, Ti, TiN, W, and TiW.

11. The semiconductor apparatus according to claim 6, wherein the first metal main electrode and the metal gate interconnect have a generally equal thickness.

12. The semiconductor apparatus according to claim 6, wherein the conductive member is made of any of Al and Cu.

13. The semiconductor apparatus according to claim 6, wherein the first metal main electrode is made of Al.

14. The semiconductor apparatus according to claim 6, wherein the semiconductor device is a MOSFET, and the first main electrode is a source electrode.

15. A semiconductor apparatus comprising:
a semiconductor device including a semiconductor layer, a first metal main electrode provided on the semiconductor layer and having a first region and a second region, and a metal gate interconnect provided on the semiconductor layer and insulated from and interposed between the first region and the second region;
a lead; and
a conductive member made of a metal and connecting the first metal main electrode to the lead,
the conductive member being spaced from the metal gate interconnect via an insulating layer made of an insulating material, and being bonded to the first region and the second region so as to cover the metal gate interconnect.

16. The semiconductor apparatus according to claim 15, wherein the conductive member has a recess on its lower surface above the metal gate interconnect.

17. The semiconductor apparatus according to claim 15, wherein the first metal main electrode and the metal gate interconnect have a generally equal thickness.

18. The semiconductor apparatus according to claim 15, wherein the conductive member is made of any of Al and Cu.

19. The semiconductor apparatus according to claim 15, wherein the first metal main electrode is made of Al.

20. The semiconductor apparatus according to claim 15, wherein the semiconductor device is a MOSFET, and the first main electrode is a source electrode.
